(19) United States
(12) Patent Application Publication
(10) Pub. No.: US 2009/0251857 A1
(43) Pub. Date: Oct. 8, 2009

(54) SYSTEM INCLUDING AN ELECTRONIC MODULE WITH A HEAT SPREADER

(75) Inventors: Anton Legen, Muenchen (DE); Steve Wood, Muenchen (DE); Lutz Morgenroth, Muenchen (DE)

Correspondence Address: DICKE, BILLIG & CZAJA, FIFTH STREET TOWERS, 100 SOUTH FIFTH STREET, SUITE 2250, MINNEAPOLIS, MN, 55402, US

(73) Assignee: QIMONDA AG, Muenchen (DE)

(21) Appl. No.: 12/098,801

(22) Filed: Apr. 7, 2008

(51) Int. Cl. H05K 7/20

(52) U.S. Cl. 361/689; 361/716

(57) ABSTRACT

A system including an electronic module with a heat spreader. One embodiment provides a plate including a thermally conductive material and a guiding member arranged along an edge of the plate. The plate and the guiding member of the heat spreader are configured to form, when attached to a first memory module, together with another heat spreader attached to a second memory module or together with a wall of another device, a duct channeling a flow of a coolant.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated as they become better understood by reference to the following detailed description. The elements of the drawings are not necessarily to scale relative to each other. Like reference numerals designate corresponding similar parts.

FIG. 1 illustrates a schematic view of a cross section of a printed circuit board, electronic modules and heat spreaders.

FIG. 2 illustrates a schematic view of a cross section of a printed circuit board, electronic modules and heat spreaders.

FIG. 3 illustrates a schematic view of a cross section of a printed circuit board, electronic modules and heat spreaders.

FIG. 4 illustrates a schematic view of a cross section of a printed circuit board, electronic modules and heat spreaders.

FIG. 5 illustrates a schematic view of a cross section of a printed circuit board, electronic modules and heat spreaders.

FIG. 6 illustrates a schematic view of a cross section of a printed circuit board, electronic modules and heat spreaders.

FIG. 7 illustrates a schematic view of a cross section of a printed circuit board, electronic modules and heat spreaders.

FIG. 8 illustrates a schematic view of a cross section of a printed circuit board, electronic modules and heat spreaders.

FIG. 9 illustrates a schematic perspective view of an electronic module with heat spreaders.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing,” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise.

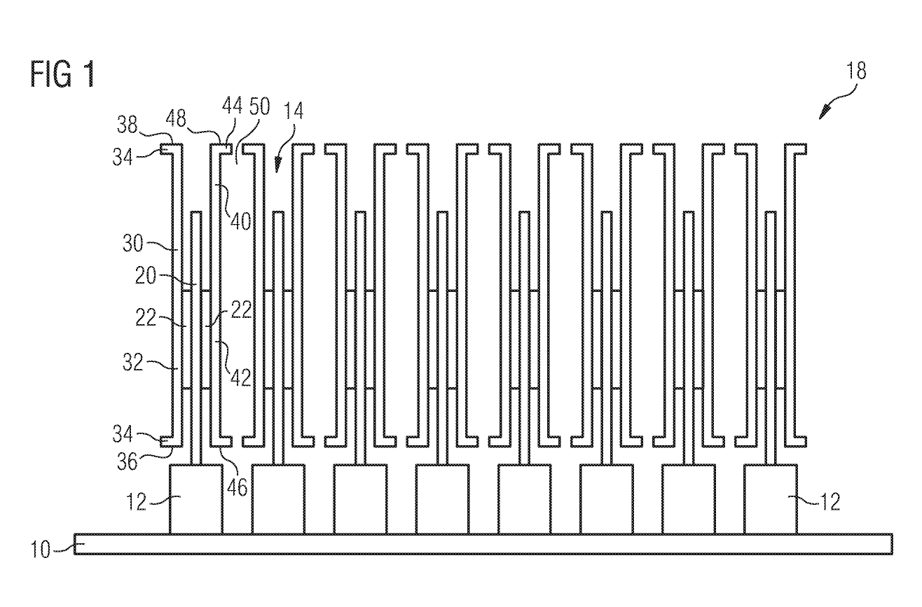

FIGS. 1 to 8 display schematic views of cross sections of printed circuit boards 10 with a number of electronic modules each. In each of the FIGS. 1 to 8, the printed circuit board 10 provides a number of electronic module sockets or electronic module slots 12. The electronic module slots 12 are arranged close to each other and parallel to each other. In each of the FIGS. 1 to 8, the plane of the cross section is perpendicular to the printed circuit board 10 and perpendicular to main planes of electronic modules 14 inserted into the electronic module slots 12.

Into each of the electronic module slots 12, an electronic module 14 including a module board 20 and one or several integrated circuits 22 arranged on one side or on both sides of the module-board 20 can be inserted. Both of the electronic module slots 12 and the module boards 20 provide electrical contacts, for example spring contacts at the electronic module slots and pins or conductor paths at the module boards 20. When a module board 20 of an electronic module is inserted into one of the electronic module slots 12, each pair of a contact of the electronic module slot 12 and a corresponding contact of the module board 20 forms an electrically conductive connection between the printed circuit board 10 and the electronic module. In this way, a large number of independent electrically conductive connections between the printed circuit board 10 and each electronic modules 14 inserted into one of the electronic module slots 12 can be formed.

The printed circuit board 10 with the electronic module slots 12 and the electronic modules 14 inserted into the electronic module slots 12 form an electronic system 18. The electronic system 18 can provide a fan or a pump or any other source of a gaseous or liquid coolant, the source pumping or blowing or circulating the coolant at least between the electronic modules 14.

As an example, the electronic system 18 is a computer or computer system, and the printed circuit board 10 is a main board or mother board of the computer or computer system, the main board usually including a processor and other integrated circuits. In this case, the electronic modules 14 can be memory modules, each memory module including a number of DRAM, SRAM, PCRAM, CBRAM or other memory devices. Throughout this application, a memory module is any arrangement of one or several memory devices, or memory chips, on one or both sides of any kind of printed circuit board.

Instead of being memory modules providing data storage capacity, the electronic modules 14 can be other kinds of modules providing another kind of functionality. For example, the electronic modules may provide I/O interfaces, processors, graphic engines, ADC or DAC converters or any other functional devices. All electronic modules inserted into the electronic module slots 12 of the printed circuit board 10 may be of the same type, or electronic modules of a number of different types may be inserted into the electronic module slots 12 of the printed circuit board 10.

As a further example, the electronic system is a server or a main frame computer, and the printed circuit board 10 is a backplane without any active electronic devices provided directly on the backplane. Such backplanes are frequently used in larger servers or in main frame computers. In this case, each of the electronic modules 14 typically includes at least one processor, a memory controller, memory devices, I/O interfaces etc.

In all the electronic systems 18 displayed in FIGS. 1 to 8, each electronic module 14 is provided with a first heat spreader 30 and a second heat spreader 40 at both opposite sides of the electronic module 14. Each heat spreader 30, 40 is in direct contact with or at least thermally conductively connected to one or more or all of the integrated circuits 22 on one side of the module board 20.

During operation, heat is dissipated in each of the integrated circuits 22. Each heat spreader 30, 40 spreads this heat over the heat spreader's 30, 40 entire surface which is usually larger or much larger than the surfaces of the integrated circuits 22. For this purpose, each heat spreader 30, 40 is as long and as wide as reasonably possible. In one embodiment, each heat spreader's 30, 40 length (measured in a direction perpendicular to the cross section displayed in the FIGS. 1 to 8) is at least almost as large as the length of the corresponding module board 20. The first edge 36, 46 of each heat spreader 30, 40 is arranged close to the electronic module slot 12 when the electronic module 14 is inserted into the electronic module slot 12. A distance between a first edge 36, 46 and a parallel second edge 38, 48 of each heat spreader 30, 40 (width of the heat spreader 30, 40) can be as large as reasonably possible, in one embodiment as large as compatible with corresponding industry standards for the respective electronic modules 14.

Each heat spreader 30, 40 includes a thermally conductive material, for example copper, aluminum, brass, gold, steel or any other metal, graphite, a thermally conductive ceramic or plastic material etc. A thermally conductive paste or any other thermally conductive viscous or liquid material can be provided between a heat spreader 30, 40 and an electronic module 14, in one embodiment between a heat spreader 30, 40 and one or several integrated circuits 22. A thermally conductive glue, or adhesive, can be provided between a heat spreader 30, 40 and an electronic module 14, in one embodiment between a heat spreader 30, 40 and one or several integrated circuits 22. A thermally conductive glue, or adhesive can provide or support a mechanical interconnection or bond between a heat spreader 30, 40 and an electronic module 14.

Referring to FIG. 1, each heat spreader 30, 40 includes a substantially flat plate 32, 42 and lip members or guiding members 34, 44 at both the first edges 36, 46 and the second edges 38, 48 of the plates 32, 42. The guiding members 34, 44 are oriented substantially perpendicular to the plates 32, 42. For each heat spreader 30, 40 the plate 32, 42 and the guiding members 34, 44 are integral. When the heat spreader 30, 40 is made of a sheet metal, the guiding members 34, 44 are formed by bending edge portions of an originally flat blank.

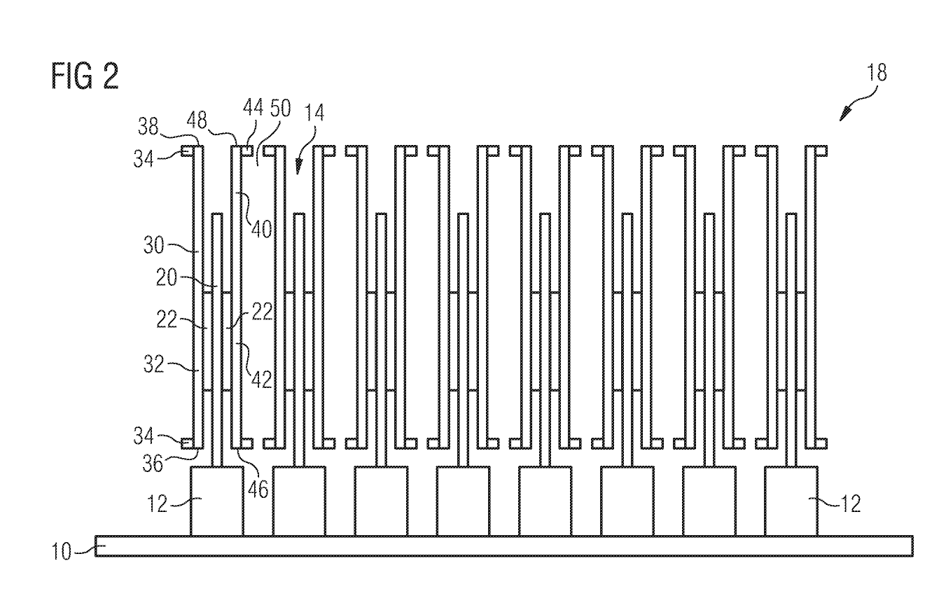

Referring to FIG. 2, heat spreaders 30, 40 differ from the heat spreaders described above with reference to FIG. 1 in that plates 32, 42 and guiding members 34, 44 are not integral. Rather, the guiding members 34, 44 are formed separate from the plates 32, 42 and than attached to the plates 32, 42. The material of the guiding members 34, 44 may be different from the material of the plates 32, 42. The guiding members 34, 42 may be connected to the plates 32, 42 by welding, soldering, gluing, crimping, riveting, or other connecting techniques.

Referring to both embodiments described above with reference to FIGS. 1 and 2, the dimensions of the guiding member 34, 44 can be selected such that a small or very small gap remains between guiding members 34, 44 of heat spreaders 30, 40 attached to electronic modules 14 inserted into two neighboring electronic module slots 12. The cap remaining between guiding members 34, 44 is in one embodiment smaller or much smaller than (for example 50%, 30% or only 10% of) the distance between plates 32, 42 of the corresponding heat spreaders 30, 40.

The plates 32, 42 and guiding members 34, 44 of heat spreaders 30, 40 attached to opposite sides of two electronic modules inserted into two neighboring electronic module slots 12 form a duct 50. Cooling air or any other gaseous or liquid coolant medium moving in a direction substantially perpendicular to the cross sections displayed in the FIGS. 1 to 8 is channeled by the ducts 50. The smaller the distance between neighboring guiding members 34, 44 of heat spreaders 30, 40 at neighboring electronic modules is, the better can be the channeling effect of the ducts 50. Channeling the movement of a coolant medium between the heat spreaders 30, 40 can intensify the transition of heat from the heat spreader 30, 40 to the coolant medium and improve the cooling effect, thereby reducing the temperature and improving performance and lifetime of the integrated circuits 22.

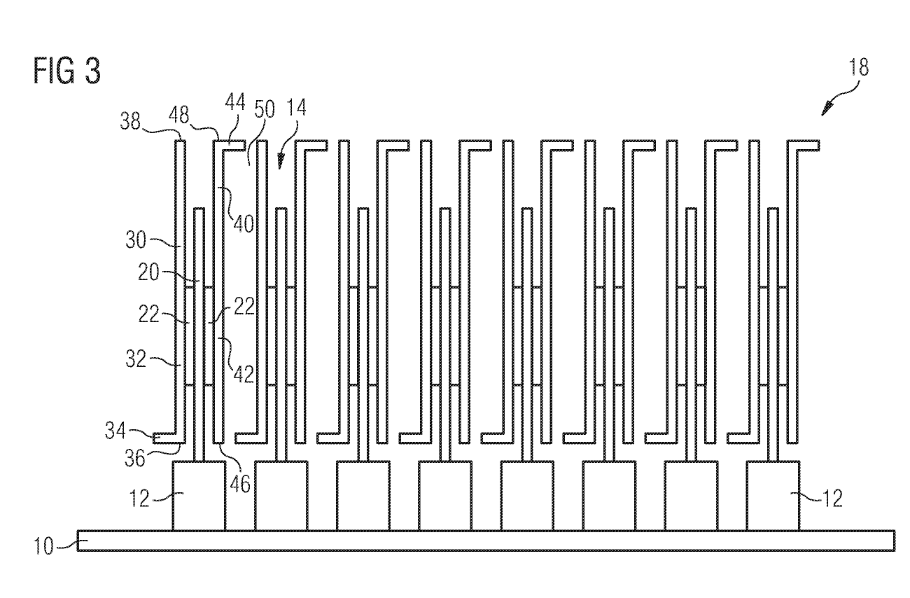

Referring to FIG. 3, each heat spreader 30, 40 provides merely one guiding member 34, 44 either at its first edge 36 or its second edge 48. To each electronic module 14, a first heat spreader 30 including a guiding member 34 at its first edge 36 and a second heat spreader 40 including a guiding member 44 at its second edge 48 are attached. Between each pair of electronic modules 14 inserted into two neighboring electronic module slots 12, the second heat spreader 40 including a guiding member 44 at its second edge 48 and a first heat spreader 30 including a guiding member 34 at its first edge 36 form a duct 50. These ducts 50 may improve the cooling of the integrated circuits 22 as described above with reference to FIGS. 1 and 2.

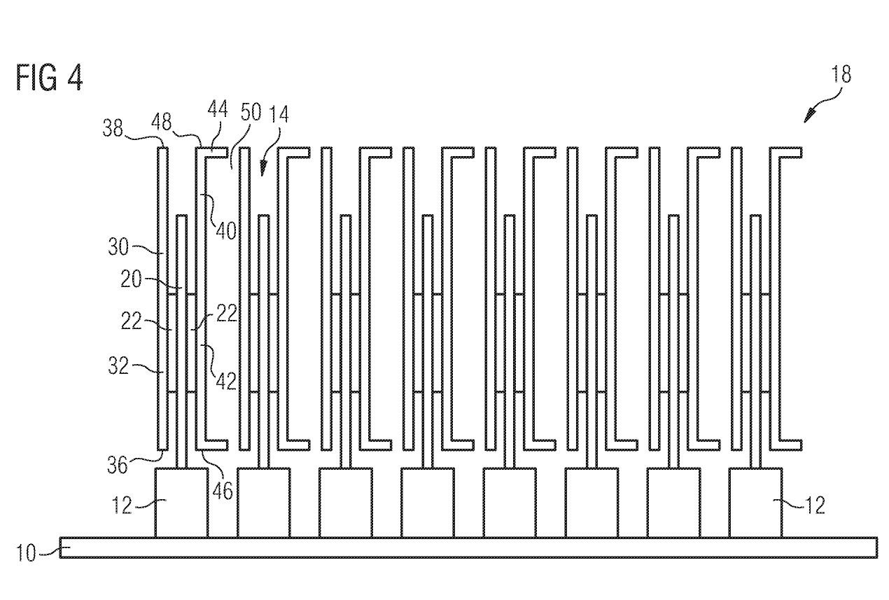

Referring to FIG. 4, a first heat spreader 30 including no guiding member and a second heat spreader 40 including guiding members 44 both at its first edge 46 and at its second edge 48 are attached to each electronic module.

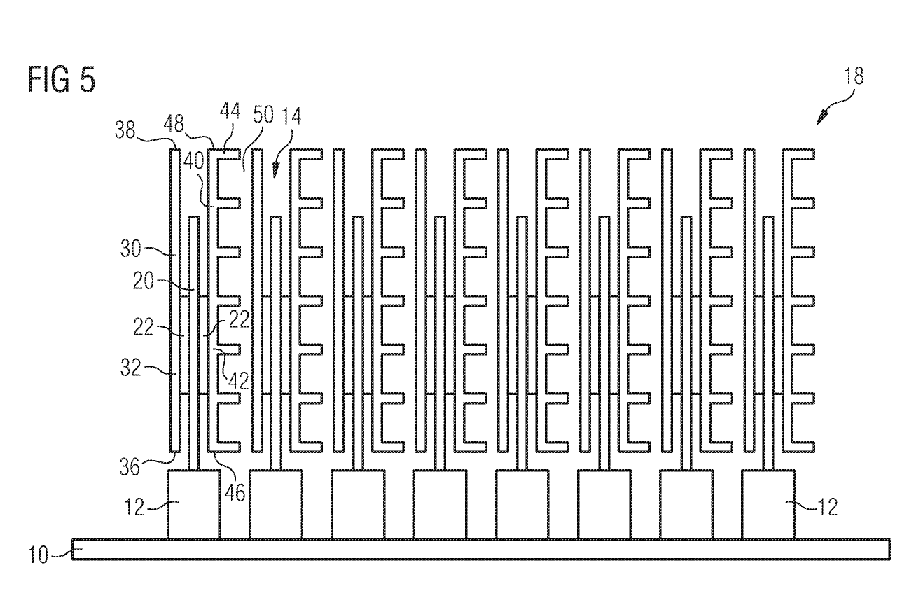

Referring to FIG. 5, a first heat spreader 30 without any guiding members and a second heat spreader 40 including guiding members 44 both at its first edge 46 and at its second edge 48 are attached to each electronic module. Furthermore, one or several additional guiding members 44 of the second heat spreader 40 are arranged between its edges 46, 48. A total number of guiding members 44 at the second heat spreader 40 is three or more. The guiding members 44 of the second heat spreader 40 are equidistantly arranged.

Between the plate 42 and the guiding members 44 of the second heat spreader 40 attached to a first electronic module 14 inserted into the first electronic module slot 12 and the plate 32 of the first heat spreader 30 attached to a second electronic module 14 inserted into a second electronic module slot 12 next to the first electronic module slot, a number of ducts are formed. The cross sections of these ducts 50 are essentially equal to each other. As an alternative, the distances between neighboring guiding members 44 of the second heat spreader 40 are different from each other. In this case, the cross sections of the ducts 50 are different from each other.

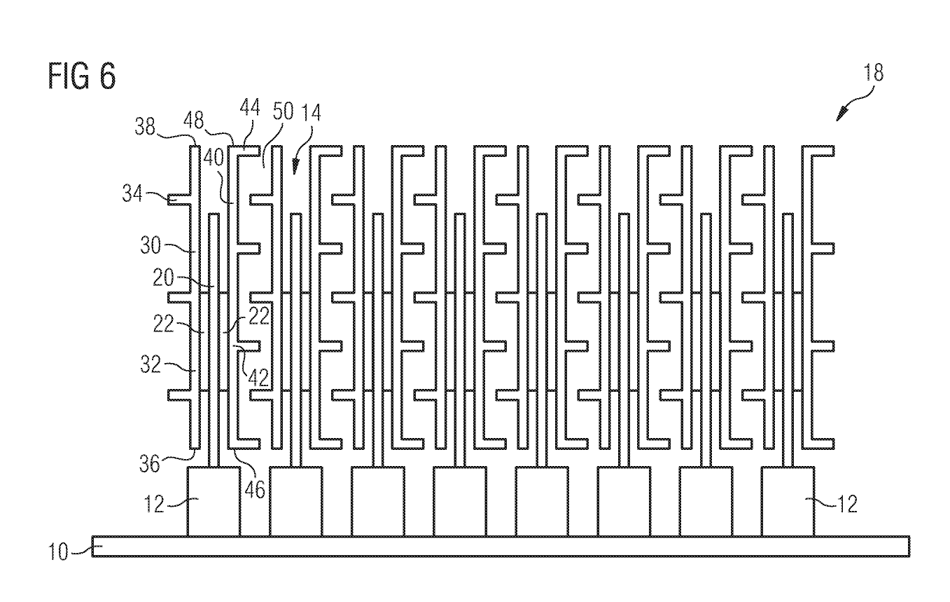

Referring to FIG. 6, a first heat spreader 30, including a first number of guiding members 34 and a second heat spreader 40 including a second number of guiding members 44 are attached to each electronic module 14. The guiding members 34 of the first heat spreaders 30 and the guiding members 44 of the second heat spreader 40 are arranged such that a number of ducts 50 are formed between the plate 42 and the guiding members 44 of a second heat spreader 40 attached to a first electronic module 14 inserted to a first electronic module slot 12 and the plate 32 and guiding members 34 of a first heat spreader 30 attached to a second electronic module 14 inserted into a second electronic module slot 12 next to the first electronic module slot. The total number of duct is three or more. Either a guiding member 34 is provided at the first edge 36 of the first heat spreader 30 or a guiding member 44 is provided at the second edge 46 of the second heat spreader 40. Either a guiding member 34 is provided at the second edge 38 of the first heat spreader 30 or a guiding member 44 is provided at the second edge 48 of the second heat spreader 40.

The cross sections of the ducts 50 can be equal to each other or different from each other. The cross sections of the ducts 50 are equal to each other when a number of guiding members 34 of the first heat spreader 30 equals or is different by one from the number of guiding members 44 of the second heat spreader 40, when the distances between guiding members 34 of the first heat spreader 30 are equal to the distances between the guiding members 44 of the heat spreader 40, and when the guiding members 34 of the first heat spreaders 30 are offset with respect to the guiding members 44 of the second heat spreader 40 by one half of the distance between two neighboring guiding members 34 or between two neighboring guiding members 44.

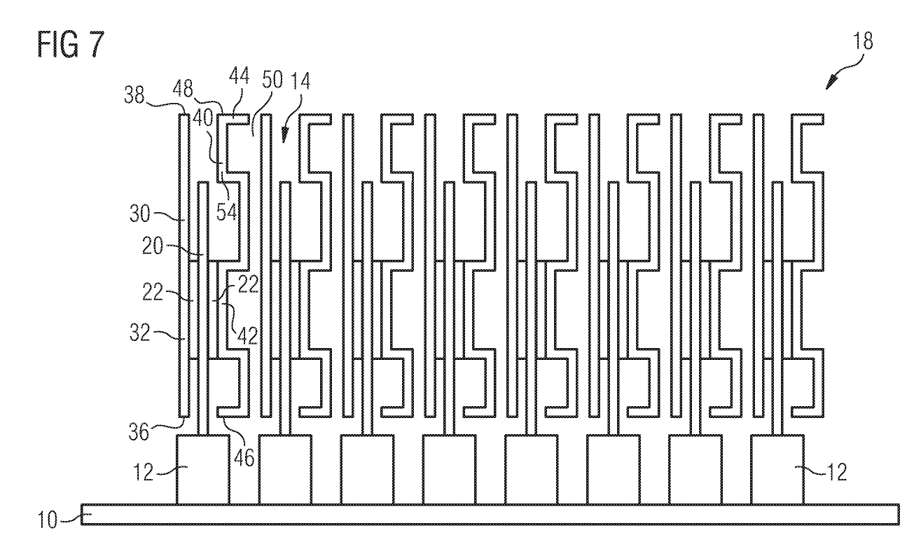

While each of the heat spreaders 30, 40 described above with reference to FIGS. 1 to 6 provides an essentially flat plate 32, 34 heat spreaders may provide a more complex cross section, too. Referring to FIG. 7, a first heat spreader 30 including a substantially flat plate 32 but no guiding members and a second heat spreader 40 are attached to each electronic module 14. The second heat spreader 40 includes a non-flat plate 32 with a number of bends 54 and a guiding member 44 at its first edge 46 or a guiding member 44 at its second edge 48 or guiding members 44 at both its first edge 46 and at its second edge 48. One or more ducts 50 are formed between the second heat spreader 40 attached to a first electronic module 14 inserted into a first electronic module slot 12 and a first heat spreader 30 attached to a second electronic module 14 inserted into a second electronic module slot 12 next to the first electronic module slot. Additionally, one or more ducts 50 may be formed between a second heat spreader 40 attached to an electronic module 14 and the module board 20 of the electronic module 14.

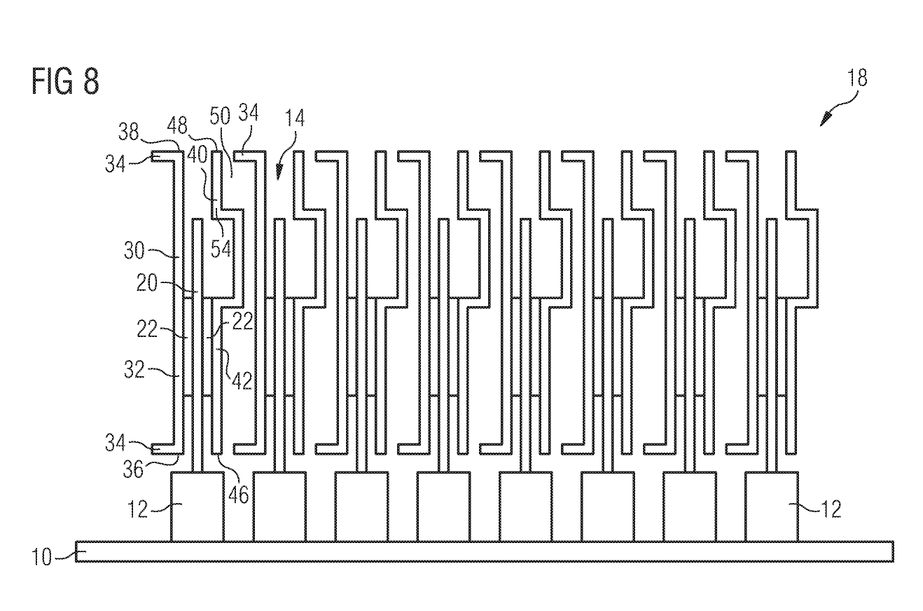

Referring to FIG. 8, a first heat spreader 30 including an essentially flat plate 32 and a guiding member 34 at its first edge 36 and/or a guiding member 34 at its second edge 38 and a second heat spreader 40 including a non-flat plate 42 are attached to each electronic module. As an alternative, each second heat spreader 40 may include a guiding member 44 at its first edge 46 and/or at its second edge 48. The plate 42 of the second heat spreader 40 includes a number of bends 54.

One or more ducts 50 are formed between a second heat spreader 40 attached to a first electronic module 14 inserted into a first electronic module slot 12 and a first heat spreader 30 attached to a second electronic module 14 inserted into a second electronic module slot 12 next to the first electronic module slot. Additionally one or more ducts 50 may be formed between the second heat spreader 40 attached to an electronic module 14 and the module board 20 of the electronic module 14.

As discussed above with reference to FIGS. 1 and 2 channeling of a coolant medium and cooling performance are improved with decreasing gaps, or distances between a guiding member 34 of a first heat spreader 30 and an opposing plate 42 or guiding member 44 of a second heat spreader 40 or between a guiding members 44 of the second heat spreader 40 and an opposing plate 32 or guiding member 34 of a first heat spreader 30. In all the embodiments described above with reference to the FIGS. 1 to 8, the distance between a guiding member 35 of the first heat spreader and the opposing plate 42 or guiding member 44 of a neighboring second heat spreader 40 and the distance between a guiding member 44 of a second heat spreader 40 and an opposing plate 32 or guiding member 34 of a first heat spreader 30 are 50% or 40 percent or 30% or 20% or 10% of the distance of the corresponding plates 32, 42 or even less.

Frequently the distance between electronic modules (defined by the distance between electronic module slots 12) is rather small. The resistance for the flow of air or any other gaseous or liquid coolant through the ducts 50 may be reduced by increasing the height (measured in a direction perpendicular to the printed circuit board 10) of each duct 50. The height may be greater than the widths or may be at least twice the width of the ducts 50. For this purpose, the width of each guiding member 34, 44 is less than or less than one half or less than one quarter of the distance between two guiding members 34, 44 of the same heat spreader 30, 44.

In all the embodiments described above with reference to the FIGS. 1 to 8, the cross section of each duct 50 is constant along the direction of flow of air or any other gaseous or liquid coolant. As an alternative, the cross section of one or several or all ducts 50 varies along the direction of flow of the coolant.

Similar to the embodiments described above with reference to FIGS. 1 and 2, the guiding members 34, 44 of the embodiments described above with reference to FIGS. 3 to 8 can be integral with the corresponding plates 32, 42 or can be formed separately and than attached to the corresponding plates 32, 42 as described above with reference to FIGS. 1 and 2.

In all the embodiments, variants and alternatives described throughout this application, the guiding members 34, 44 may be oriented essentially perpendicular to the respective plates 32, 42. As an alternative, the angle between a plate 32, 42 and a respective guiding member 34, 44 can be any angle greater than 0° and less than 180°. In one embodiment, the angle between a plate 32, 42 and a respective guiding member 34, 44 can be in the range from 60° to 120°.

Any bending radius can be provided between a plate 32, 42 and a respective guiding member 34, 44, in one embodiment when the plate 32, 42 and the respective guiding member 34, 44 are integral. In one embodiment, a bending radius substantially equaling the thickness of the plate 32, 42 or the thickness of the guiding member 34, 44 or substantially equaling half the distance between two heat spreaders arranged at two neighboring electronic modules 14 can be provided.

In all the embodiments, variants and alternatives described throughout this application, the guiding members 34, 44 may be curved in the direction perpendicular to the planes of the cross-sections displayed in the Figures. For example, the guiding members can be undulated or wavelike, looking like a series of waves when viewed from the side. In all cases, the cross sections of the guiding members 34, 44 can be constant or essentially constant or vary along the guiding members 34, 44. Any deviation of the guiding members 34, 44 from a straight linear shape could facilitate of improve the transfer of heat from the heat spreader to a gaseous or liquid coolant.

In some of the embodiments described above, in one embodiment in the embodiments described above with reference to FIGS. 4, 5 and 7 including first heat spreaders 30 without any guiding member, and in one embodiment in case of electronic modules 14 including integrated circuits 22 only at one side of the module board 20, merely one heat spreader may be attached to each electronic module. In case of the embodiments described above with reference to FIGS. 4, 5 and 7, the first heat spreader 30 can be omitted, in one embodiment when no integrated circuit 22 is provided on the corresponding side of the corresponding module board 20. In this case, the widths of the guiding members 44 of the remaining second heat spreaders 40 may be increased thereby ranging close to the module board 20 or the heat spreader 40 of the neighboring electronic module.

In the embodiments described above with reference to FIGS. 1 to 8, the electronic modules 14 inserted into the electronic module slots 12 are equal to each other. As an alternative, in each of the embodiments described above with reference to FIGS. 1 to 8, electronic modules 14 more or less different from each other may be inserted into the electronic module slots 12. Furthermore, the number of electronic module slots 12 and the number of electronic modules 14 may be different from 8.

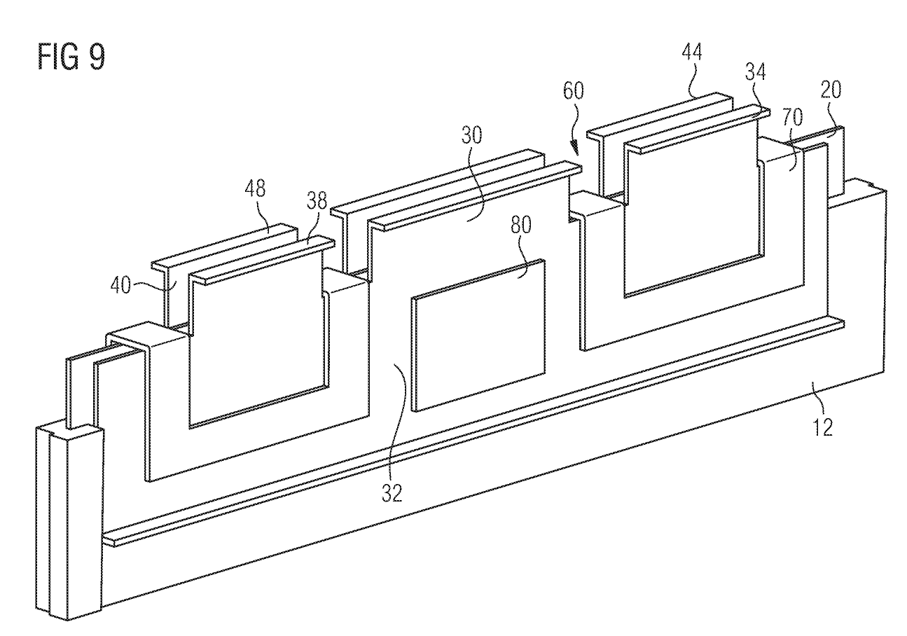

FIG. 9 is a schematic perspective view of an electronic module with heat spreaders 30, 40. The electronic module includes a module board 20 and integrated circuit 22 which are hidden behind the heat spreader 30. Spring clips 70 compress the stack formed by the first heat spreader 30, the module board 20 with the integrated circuits, and the second heat spreader 40, thereby fixing the heat spreaders 30, 40 to the electronic module and facilitating the transition of heat from the integrated circuits to the heat spreaders 30, 40. Instead of two spring clips, one spring clip can be used, too. The electronic module 14 is inserted into an electronic module slot 12 as described above with reference to FIGS. 1 to 8.

Recesses 60 at the second edges define the position of the spring clips 70 and allow for a reduced size of each spring clip 70. The recesses 60 facilitate a flow of coolant between the ducts 50 and the ambient. The number, size and position of the recesses 60 can be adjusted for an optimum flow of coolant and an optimum cooling effect. In one embodiment the distribution of pressure, velocity and turbulences within the ducts can be optimized. Recesses 60 and/or spring clips 70 can be provided in any of the embodiments described above with reference to the FIGS. 1 to 8, too.

In order to accommodated and advanced memory buffer or any other integrated circuit with increased hate, a slightly raised section 80 may be provided within the plate 32 of at least one of the heat spreaders 30, 40. More generally, the different heights of integrated circuits on a module board 20 may be compensated for by corresponding deviations of the plates 32, 42 from the perfectly flat shape. This applies to all the embodiments described above with reference to the FIGS. 1 to 8, too.

As can be seen from the FIGS. 1 to 9, in most of the embodiments described above with reference to the Figures, the guiding members 34, 44 of the heat spreaders and the integrated circuits 22 are arranged at different or opposite sides of the plates 32, 42.

In the embodiments described above with reference to the Figures, one or several ducts are formed between heat spreaders 30, 40 attached to two different electronic modules 14. In one embodiment, one or several ducts are formed between heat spreaders 30, 40 attached to two electronic modules 14 inserted into two neighboring electronic module slots 12. As an alternative, one or several ducts are formed between a heat spreader 30, 40 as described above with reference to the Figures and a wall arranged opposite to the heat spreader. As an example, the wall can be an inner wall of a housing of an apparatus including the electronic module slot 12 into which the respective electronic module 114 is inserted, or the wall can be a part of an outer surface of another component of the apparatus.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

1. An electronic system comprising a plurality of electronic modules arranged essentially parallel to each other, each electronic module comprising a heat spreader, each heat spreader comprising:
a plate comprising a thermally conductive material; and
a guiding member arranged along an edge of the plate,
wherein the plate and the guiding member of the heat spreader of a first electronic module are configured to form, together with a heat spreader attached to a second electronic module or together with a wall of the electronic system or of another device, a duct channeling a flow of a coolant.

2. The electronic system of claim 1, comprising wherein the electronic system is a computer system.

3. The electronic system of claim 1, comprising wherein the electronic modules are memory modules.

4. The electronic system of claim 1, further comprising:
a circuit board with a plurality of electronic module slots, wherein each of the electronic modules are inserted into one of the electronic module slots.

5. The electronic system of claim 1, further comprising:
a source of coolant, the source providing or blowing or pumping or circulating a gaseous or fluid coolant at least between the first and second electronic modules.

6. A heat spreader for a memory module, the heat spreader comprising:
a plate comprising a thermally conductive material; and
a guiding member arranged along an edge of the plate,
wherein the plate and the guiding member are configured to form, when attached to a first memory module, together with another heat spreader attached to a second memory module or together with a wall of another device, a duct channeling a flow of a coolant.

7. The heat spreader of claim 6, comprising wherein the heat spreader essentially covers at least one side of the memory module.

8. The heat spreader of claim 6, wherein the heat spreader comprises a plurality of guiding members, and wherein the width of each of the plurality of guiding members is less than or less than one half or less than one quarter of the distance between two neighboring guiding members.

9. The heat spreader of claim 6, comprising wherein the heat spreader is configured such that two heat spreaders of the same kind attached to two memory modules together form a duct channeling a flow of a coolant between the two heat spreaders.

10. The heat spreader of claim 6, comprising wherein the plate and the guiding member of the heat spreader, when attached to a first memory module, together with another heat spreader attached to a second memory module, form a duct channeling a flow of a coolant between the heat spreader of the first memory module and the heat spreader of the second memory module.

11. The heat spreader of claim 6, comprising wherein the plate and the guiding member of the heat spreader, when attached to a first memory module in a first memory module slot of a circuit board, together with a plate and a guiding member of another heat spreader attached to a second memory module in a second memory module slot adjacent to the first memory module slot, form a duct channeling a flow of a coolant between the heat spreader of the first memory module and the heat spreader of the second memory module.

12. The heat spreader of claim 6, comprising wherein the plate and the guiding member are integral.

13. The heat spreader of claim 6, comprising:
two guiding members arranged along opposite edges of the plate.

14. The heat spreader as claimed in claim 6, further comprising at least one recess in the guiding member, the recess accommodating a spring clip fixing the heat spreader to a memory module when the heat spreader is fixed to the memory module.

15. A memory module comprising:
a memory chip;
a heat spreader, the heat spreader comprising:
a plate comprising a thermally conductive material; and
a guiding member arranged along an edge of the plate,
wherein the plate and the guiding member of the heat spreader of the memory module are configured to form, together with another heat spreader attached to another memory module or together with a wall of another device, a duct channeling a flow of a coolant.

16. The memory module of claim 15, comprising wherein the heat spreader essentially covers at least one side of the memory module.

17. The memory module of claim 15, wherein the heat spreader comprises a plurality of guiding members, and wherein the width of each of the plurality of guiding members is less than or less than one half or less than one quarter of the distance between two neighboring lip members.

18. The memory module of claim 15, comprising wherein the heat spreader is configured such that the heat spreaders of the memory modules together with the heat spreader of another memory module of the same kind together form a duct channeling a flow of a coolant between the heat spreaders of the memory modules.

19. The memory module of claim 15, comprising wherein the plate and the guiding member of the heat spreader, together with a heat spreader of another memory module, form a duct channeling a flow of a coolant between the heat spreader of the memory module and the heat spreader of the other memory module.

20. An Electronic module comprising:
a module board;
an integrated device associated with the module board; and
a heat spreader comprising:
a plate comprising a thermally conductive material; and
a guiding member arranged along an edge of the plate,
wherein the heat spreader is configured such that the heat spreader of the electronic module and a heat spreader of another electronic module of the same kind together form a duct channeling a flow of a coolant between the heat spreaders.

21. The electronic module of claim 20, wherein the heat spreader comprises a plurality of guiding members, and wherein the width of each of the plurality of guiding members is less than or less than one half or less than one quarter of the distance between two neighboring guiding members.
